(19) United States
(12) Patent Application Publication
(10) Pub. No.: US 2024/0421728 A1
(43) Pub. Date: Dec. 19, 2024

(54) ACOUSTIC DETECTION SYSTEM AND METHOD AND ASSOCIATED KINETIC ENERGY HARVESTER

(71) Applicant: The Boeing Company, Arlington, VA (US)

(72) Inventors: James Y. Lee, La Habra, CA (US); Li C. Chang, Mt. Pleasant, SC (US)

(21) Appl. No.: 18/335,692

(22) Filed: Jun. 15, 2023

(51) Int. Cl. H02N 2/18; B64D 45/00; B81B 3/00; G01H 1/14; G01H 1/16; H02J 50/00; H02K 35/02

(52) U.S. Cl. CPC H02N 2/186; B64D 45/00; B81B 3/0021; G01H 1/14; G01H 1/16; H02J 50/001; H02K 35/02; B64D 2045/0085; B81B 2201/0285; B81B 2207/053

(57) ABSTRACT

An acoustic detection system and method and associated kinetic energy harvester is disclosed. The acoustic detection system comprises a vibration-generating object, a kinetic-energy harvester, and an acoustic sensor. The kinetic-energy harvester is embedded within a first location of the vibration-generation object and is configured to wirelessly transmit electrical power to the acoustic sensor, which is embedded within a second location of the vibration-generating object. The acoustic sensor is configured to receive the electrical power, detect acoustic signals, and convert the detected acoustic signals into acoustic data. The kinetic energy harvester may be an electromagnetic harvester that comprises a magnet array and a coil array comprising at least one conductive coil. By inducing a current in the at least one conductive coil through the relative motion between the magnet array and the coil array, the kinetic-energy harvester produces electrical power.

### FIELD

This disclosure relates generally to an acoustic detection system, and more particularly to an acoustic detection system powered by a kinetic energy harvester.

### BACKGROUND

Aircraft are vulnerable to a wide range of internal and external factors that can cause damage or performance issues to the aircraft during flight. These factors may include lightning, hail, and bird strikes to the aircraft, as well as cracks or corrosion, and problems with misaligned, loose, or broken internal parts on or within the aircraft. Typically, aircraft crew identify and report any damage or performance issues during flight to a ground crew which performs further visual inspections of the aircraft upon landing. However, it is common for damage or performance issues to be over or under reported, or in some cases, completely missed as it is difficult for aircraft crew and ground crew to identify or fully assess any resulting damage or performance issues. This can result in longer-than-necessary aircraft on-ground (AOG) time for identification of damage or performance issues and/or for necessary repairs of the aircraft, which are both time-consuming and expensive. Furthermore, improper identification of damage or performance issues can lead to incomplete or inadequate repairs, potentially compromising the airworthiness of the aircraft. Moreover, it can be challenging to carry out preventive and proactive maintenance to the aircraft in a targeted and cost-effective manner.

### SUMMARY

The subject matter of the present application has been developed in response to the present state of the art, and in particular, in response to the problems of and needs created by, or not yet fully solved by, typical reporting of damage and performance issues to aircraft. Generally, the subject matter of the present application has been developed to provide an acoustic detection system and method and associated kinetic energy harvester that overcomes at least some of the above-discussed shortcomings of prior art techniques.

Disclosed herein in an acoustic detection system. The acoustic detection system includes a vibration-generating object. The acoustic detection system also includes a kinetic-energy harvester embedded within a first location of the vibration-generating object. The kinetic-energy harvester is configured to convert vibrations, at the first location of the vibration-generating object when the vibration-generating object is generating vibrations, into electrical power, and configured to wirelessly transmit the electrical power. The acoustic detection system further includes an acoustic sensor embedded within a second location of the vibration-generating object, which is separate from the first location. The acoustic sensor is configured to wirelessly receive the electrical power from the kinetic-energy harvester, detect acoustic signals proximate to the second location of the vibration-generating object using the electrical power, and convert the detected acoustic signals into acoustic data. The preceding subject matter of this paragraph characterizes example 1 of the present disclosure.

The acoustic detection system also includes a controller on the vibration-generating object configured to receive the acoustic data transmitted from the acoustic sensor and process the acoustic data to determine a current status at the second location of the vibration-generating object. The preceding subject matter of this paragraph characterizes example 2 of the present disclosure, wherein example 2 also includes the subject matter according to example 1, above.

The kinetic energy harvest includes a magnet array, a coil array, and a cantilever beam spring. The magnet array includes a plurality of magnets arranged with alternating polarity and an interface between adjacent ones of the plurality of magnets. Each magnet of the plurality of magnets forming a portion of a coil-facing surface of the magnet array. The coil array includes at least one conductive coil. The coil array is offset from the magnet array in a first direction, such that an air-gap is defined between the coil-facing surface of the magnet array and the coil array. In a second direction, parallel to the first direction, the at least one conductive coil is aligned with the interface between corresponding adjacent ones of the plurality of magnets. The cantilever beam spring is coupled with the magnet array to the coil array and configured to enable movement of the coil array, relative to the magnet array, about a vibration plane that is perpendicular to the first direction. The preceding subject matter of this paragraph characterizes example 3 of the present disclosure, wherein example 3 also includes the subject matter according to any of examples 1-2, above.

The magnet array of the kinetic-energy harvester is fixed, relative to the vibration-generating object such that the magnet array does not move relative to the vibration-generating object. The preceding subject matter of this paragraph characterizes example 4 of the present disclosure, wherein example 4 also includes the subject matter according to example 3, above.

The acoustic sensor comprises a MEMS-based acoustic sensor. The preceding subject matter of this paragraph characterizes example 5 of the present disclosure, wherein example 5 also includes the subject matter according to any of examples 1-4, above.

The acoustic detection system includes a plurality of kinetic-energy harvesters and a plurality of acoustic sensors. Each one of the plurality of kinetic-energy harvesters corresponds to exactly one of the plurality of acoustic sensors, such that the electrical power generated by each one of the plurality of kinetic-energy harvesters is wirelessly transmitted to a corresponding one of the plurality of acoustic sensors. The preceding subject matter of this paragraph characterizes example 6 of the present disclosure, wherein example 6 also includes the subject matter according to any of examples 1-5, above.

The acoustic detection system includes a plurality of kinetic-energy harvesters and a plurality of acoustic sensors. At least one of the plurality of kinetic-energy harvesters corresponds to at least two of the plurality of acoustic sensors, such that the electrical power generated by each one of the plurality of kinetic-energy harvesters is wirelessly transmitted to at least two of the plurality of acoustic sensors. The preceding subject matter of this paragraph characterizes example 7 of the present disclosure, wherein example 7 also includes the subject matter according to any of examples 1-6, above.

The vibration-generating object is an aircraft. The acoustic sensor is configured to detect acoustic signals to the aircraft for at least one of a lightning strike, a bird strike, a hail strike, a crack, a misalignment, a loose part, or a broken part. The preceding subject matter of this paragraph characterizes example 8 of the present disclosure, wherein example 8 also includes the subject matter according to any of examples 1-7, above.

Further disclosed herein is a method of detecting acoustic signals from a vibration-generating object. The method includes harvesting electrical power from vibrations within a first location of a vibration-generating object using a kinetic-energy harvester embedded within the first location of the vibration-generating object. The kinetic-energy harvester is configured to convert the vibrations into electrical power. The method also includes wirelessly transmitting the electrical power generated by the kinetic-energy harvester to an acoustic sensor embedded within a second location of the vibration-generating object, separate from the first location, to power the acoustic sensor. The method further includes detecting acoustic signals proximate to the second location of the vibration-generating object via the acoustic sensor, and processing the detected acoustic signals into acoustic data. The preceding subject matter of this paragraph characterizes example 9 of the present disclosure.

The method also includes wirelessly transmitting the acoustic data from the acoustic sensor to a controller on the vibration-generating object. The controller is configured to process the acoustic data to determine a current status of the vibration-generating object at the second location. The preceding subject matter of this paragraph characterizes example 10 of the present disclosure, wherein example 10 also includes the subject matter according to example 9, above.

The method also includes transmitting the processed acoustic data from the controller to a second controller, remote from the vibration-generating object. The second controller is configured to analyze the processed acoustic data. The preceding subject matter of this paragraph characterizes example 11 of the present disclosure, wherein example 11 also includes the subject matter according to example 10, above.

The step of harvesting electrical power from vibrations within a first location of a vibration-generating object using a kinetic-energy harvester further includes harvesting electrical power from vibrations within a plurality of first locations of the vibration-generating object using a plurality of kinetic-energy harvesters each one embedded within a corresponding one of the plurality of first locations. The step of wirelessly transmitting the electrical power generated by the kinetic-energy harvester to an acoustic sensor embedded within a second location further includes wirelessly transmitting the electrical power generated by each one of the plurality of kinetic-energy harvesters to at least one of a plurality of acoustic sensors embedded within a corresponding one of a plurality of second locations. The method further includes forming a phased array using the processed acoustic data from each one of the plurality of acoustic sensors to provide referencing for making predictive and prescriptive decisions about the vibration-generation object. The preceding subject matter of this paragraph characterizes example 12 of the present disclosure, wherein example 12 also includes the subject matter according to any of examples 10-11, above.

Further disclosed herein is a kinetic-energy harvester. The kinetic-energy harvester includes a magnet array, a coil array, and a cantilever beam spring. The magnet array includes a plurality of magnets arranged with alternating polarity and an interface between adjacent ones of the plurality of magnets. Each magnet of the plurality of magnets forming a portion of a coil-facing surface of the magnet array. The coil array includes at least one conductive coil. The coil array is offset from the magnet array in a first direction, such that an air-gap is defined between the coil-facing surface of the magnet array and the coil array. In a second direction, parallel to the first direction, the at least one conductive coil is aligned with the interface between corresponding adjacent ones of the plurality of magnets. The cantilever beam spring is coupled with the magnet array to the coil array and configured to enable movement of the coil array, relative to the magnet array, about a vibration plane that is perpendicular to the first direction. The preceding subject matter of this paragraph characterizes example 13 of the present disclosure.

A size and thickness of each one of the plurality of magnets is the same. The preceding subject matter of this paragraph characterizes example 2 of the present disclosure, wherein example 14 also includes the subject matter according to example 13, above.

The plurality of magnets includes two magnets adjacent each other. A first one of the two magnets has a first orientation. A second one of the two magnets has a second orientation. The first orientation is opposite the second orientation. The preceding subject matter of this paragraph characterizes example 15 of the present disclosure, wherein example 15 also includes the subject matter according to any of examples 13-14, above.

The coil array includes a plurality of conductive coils, the at least one conductive coil being one of the plurality of conductive coils. Each one of the plurality of conductive coils is aligned, in the second direction, with the interface between corresponding adjacent ones of the plurality of magnets. The preceding subject matter of this paragraph characterizes example 16 of the present disclosure, wherein example 16 also includes the subject matter according to any of examples 13-15, above.

The magnet array has a plurality of rows and a plurality of columns. Each magnet of the plurality of magnets has one of a first orientation or a second orientation, that is opposite the first orientation. Diagonally adjacent magnets of the plurality of magnets have a same orientation. The preceding subject matter of this paragraph characterizes example 17 of the present disclosure, wherein example 17 also includes the subject matter according to any of examples 13-16, above.

At least one conductive coil is a planar coil that is coiled in a plane co-planar with or parallel to the vibration plane. The preceding subject matter of this paragraph characterizes example 18 of the present disclosure, wherein example 18 also includes the subject matter according to any of examples 13-17, above.

The coil array includes a transmitter. The at least one conductive coil is configured to forward electrical power produced by the at least one conductive coil to the transmitter. The transmitter is configured to transfer the electrical power wirelessly to a second device using electromagnetic induction. The preceding subject matter of this paragraph characterizes example 19 of the present disclosure, wherein example 19 also includes the subject matter according to any of examples 13-18, above.

The coil array includes a base. The at least one conductive coil is fixed to the base. The preceding subject matter of this paragraph characterizes example 20 of the present disclosure, wherein example 20 also includes the subject matter according to any of examples 13-19, above.

The described features, structures, advantages, and/or characteristics of the subject matter of the present disclosure may be combined in any suitable manner in one or more examples, including embodiments and/or implementations. In the following description, numerous specific details are provided to impart a thorough understanding of examples of the subject matter of the present disclosure. One skilled in the relevant art will recognize that the subject matter of the present disclosure may be practiced without one or more of the specific features, details, components, materials, and/or methods of a particular example, embodiment, or implementation. In other instances, additional features and advantages may be recognized in certain examples, embodiments, and/or implementations that may not be present in all examples, embodiments, or implementations. Further, in some instances, well-known structures, materials, or operations are not shown or described in detail to avoid obscuring aspects of the subject matter of the present disclosure. The features and advantages of the subject matter of the present disclosure will become more fully apparent from the following description and appended claims, or may be learned by the practice of the subject matter as set forth hereinafter.

### BRIEF DESCRIPTION OF THE DRAWINGS

In order that the advantages of the subject matter may be more readily understood, a more particular description of the subject matter briefly described above will be rendered by reference to specific examples that are illustrated in the appended drawings. Understanding that these drawings depict only typical examples of the subject matter, they are not therefore to be considered to be limiting of its scope. The subject matter will be described and explained with additional specificity and detail through the use of the drawings, in which:

FIG. 1 is a schematic flow diagram of an acoustic detection system, according to one or more examples of the present disclosure;

FIG. 2 is a schematic perspective view of a kinetic-energy harvester, according to one or more examples of the present disclosure;

FIG. 3 is a schematic side elevation view of the kinetic-energy harvester of FIG. 2, according to one or more examples of the present disclosure;

FIG. 4 is a schematic top view of one example of a kinetic-energy harvester, according to one or more examples of the present disclosure;

FIG. 5 is a schematic top view of another example a kinetic-energy harvester, according to one or more examples of the present disclosure;

FIG. 6 is a schematic perspective view of an aircraft that has an acoustic detection system, according to one or more examples of the present disclosure; and

FIG. 7 is a schematic flow diagram of a method of detecting acoustic signals from a vibration-generating object, according to one or more examples of the present disclosure.

### DETAILED DESCRIPTION

Reference throughout this specification to “one example,” “an example,” or similar language means that a particular feature, structure, or characteristic described in connection with the example is included in at least one example of the subject matter of the present disclosure. Appearances of the phrases “in one example,” “in an example,” and similar language throughout this specification may, but do not necessarily, all refer to the same example. Similarly, the use of the term “implementation” means an implementation having a particular feature, structure, or characteristic described in connection with one or more examples of the subject matter of the present disclosure, however, absent an express correlation to indicate otherwise, an implementation may be associated with one or more examples.

Disclosed herein are examples of an acoustic detection system and method and an associated kinetic-energy harvester. The following provides some features of at least some examples of the acoustic detection system and method and associated kinetic-energy harvester. The acoustic detection system includes at least one kinetic-energy harvester that may be connected to any object capable of producing mechanical movements, including vibration-generating objects, allowing the kinetic-energy harvester to harness the kinetic energy present in mechanical movements and convert them into usable electrical power. In some examples, the acoustic detection system is associated with an aircraft, such that the vibrations from the aircraft are harnessed by the kinetic-energy harvester to power the acoustic detection system. Furthermore, the acoustic detection system includes an acoustic sensor that is configured to be powered by wirelessly transmitting the electrical power from the kinetic-energy harvester to the device, eliminating the need for a direct physical connection between the acoustic sensor and the kinetic-energy harvester. The acoustic sensor is strategically positioned to detect acoustic signals proximate to the vibration-generating object. After the acoustic sensor captures an acoustic signal, the acoustic signal is processed and converted into acoustic data. The acoustic data contains at least one characteristic of the detected acoustic signal, which can be used to analyze and identify the source of the acoustic signal. For example, the acoustic signal may originate from specific aircraft components, engine operations, environmental factors, or external events. The acoustic detection system enables monitoring, analysis, and identification of potential issues, anomalies, and damage to the aircraft and may contribute to enhanced safety, maintenance, and performance optimization of the aircraft. Accordingly, the acoustic detection system can enable informed decision-making and effective maintenance practices, including preventative and proactive maintenance practices.

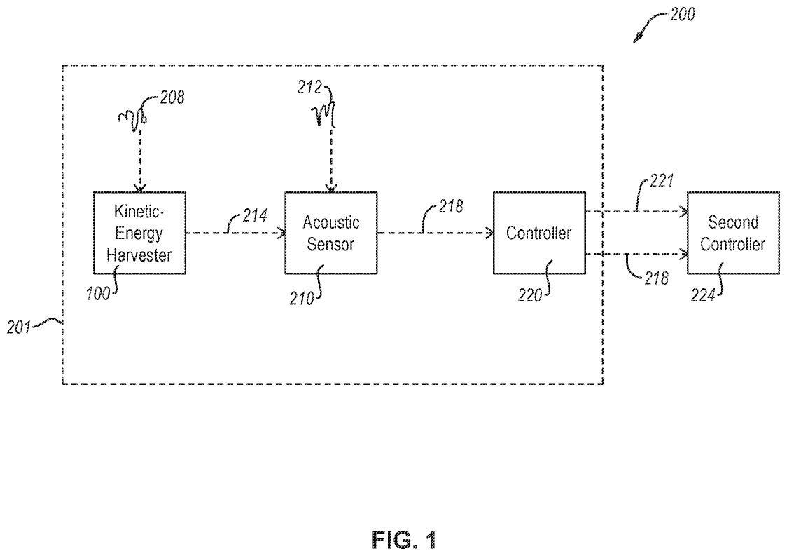

Referring to FIG. 1, one example of an acoustic detection system 200 is shown. The acoustic detection system 200 includes a kinetic-energy harvester 100 that captures mechanical movements, including vibrations 208 from a vibration-generating object 201, and converts the mechanical movements into electrical power 214. As used herein, the kinetic-energy harvester 100 is any device that can capture and convert kinetic energy from mechanical sources into usable electrical power. Mechanical sources may include various types of motion, including vibrations 208, which are converted into electrical energy for powering other devices. The kinetic-energy harvester 100 may be one of a piezoelectric, electrostatic, or electromagnetic kinetic-energy harvester.

The electrical power 214 generated by the kinetic-energy harvester 100 is wirelessly transmitted to an acoustic sensor 210 of the acoustic detection system 200, which uses the electrical power 214 to capture (e.g., detect or sense) acoustic signals 212 generated by various sources, including components of the vibration-generating object 201 or external factors or events affecting the vibration-generating object 201. The acoustic signals 212 are processed, by the acoustic sensor 210, to transform the acoustic signals 212 into acoustic data 218. The acoustic data 218 includes at least one characteristic of the acoustic signal 212, such as frequency, amplitude, duration, magnitude, voltage, or other characteristics. The acoustic sensor 210, using the electrical power 214 from the kinetic-energy harvester 100, wirelessly transmits the acoustic data 218 to a controller 220 of the acoustic detection system 200, which can be onboard the vibration-generation object 201.

In one example, the controller 220 further processes the acoustic data 218 and converts it to processed acoustic data 221. The controllers of the present disclosure are electronic controllers. The electronic controller and associated modules described in this specification may be implemented as a hardware circuit comprising custom VLSI circuits or gate arrays, off-the-shelf semiconductors such as logic chips, transistors, or other discrete components. The electronic controller may also be implemented in programmable hardware devices such as field programmable gate arrays, programmable array logic, programmable logic devices or the like. The electronic controller may also be implemented in code and/or software for execution by various types of processors. An identified module of code may, for instance, comprise one or more physical or logical blocks of executable code which may, for instance, be organized as an object, procedure, or function. Nevertheless, the executables of the electronic controller need not be physically located together, but may comprise disparate instructions stored in different locations which, when joined logically together, comprise the electronic controller and achieve the stated purpose for the electronic controller.

The processed acoustic data 221 is used to determine a current status at the location of a corresponding acoustic sensor 210, such as specific damage or performance issues of the vibration-generating object 201. In some examples, the processed acoustic data 221 may identify the origin or cause of the acoustic signal 212, such as by identifying characteristics of the acoustic data 218 that may be particular to certain types of damage or performance issues. The controller 220 can further transmit the processed acoustic data 221 to a second controller 224 of the acoustic detection system 200 that is remote from the vibration-generating object 201. In other examples, the controller 220 does not further process the acoustic data 218, such as in cases where the controller 220 does not have sufficient power or capabilities to further process the acoustic data 218, in which case the acoustic data 218 is transmitted to a second controller 224 for further processing. The processed acoustic data 221 can be used to provide insights for decision-making and maintenance practices for the vibration-generating object 201. Additionally, the information can be used, in some cases, to identify preventative or proactive concerns with the vibration-generating object 201.

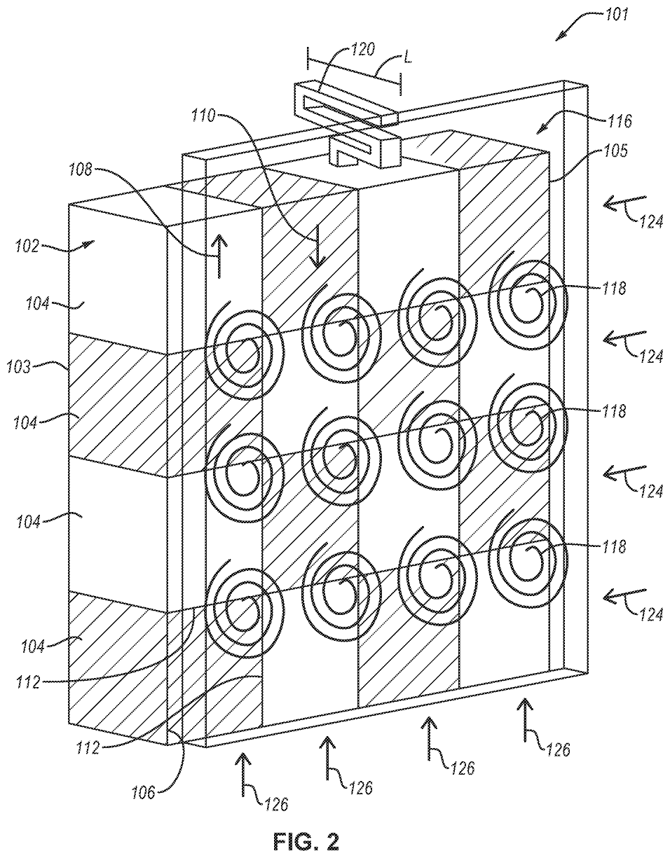

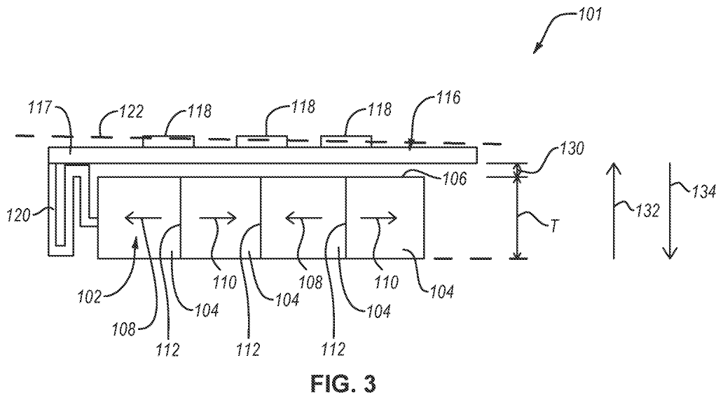

Referring to FIGS. 2 and 3, one example of the kinetic-energy harvester 100 that may be used in the acoustic detection system 200 is shown as a kinetic-energy harvester 101. The kinetic-energy harvester 101 is an electromagnetic kinetic-energy harvester that includes a magnet array 102, a coil array 116, and a cantilever beam spring 120. The magnet array 102 has a plurality of magnets 104 arranged with alternating polarity. That is, adjacent ones of the plurality of magnets 104 alternate between one of two distinct orientations (e.g., alternate between a magnet 104 having a first orientation 108 and a magnet 104 having a second orientation 110). The first orientation 108 is opposite of the second orientation 110. In some examples, as shown in FIGS. 2 and 3, the first orientation 108 of a magnet of the plurality of magnets 104 has a north pole that is facing the cantilever beam spring 120 of the kinetic-energy harvester 101, as indicated by the upward arrow in FIG. 2. The second orientation 110 of a magnet of the plurality of magnets 104 has a south pole that is facing the cantilever beam spring 120, as indicated by the downward arrow in FIG. 2.

The plurality of magnets 104 includes at least two magnets with one magnet positioned in the first orientation 108 and the other magnet positioned in the second orientation 110. This arrangement creates a pattern of alternating polarity within the magnet array 102. Accordingly, when the plurality of magnets 104 has more than two magnets, the pattern of alternating polarity continues throughout the magnet array 102. In other examples, the first orientation 108 of a magnet of the plurality of magnets 104 has a north pole that is facing the coil array 116 of the kinetic-energy harvester 101. In other words, an axis defined by the north and south pole of the magnet is parallel to a length (L) of the cantilever beam spring 120. The second orientation 110 of a magnet of the plurality of magnets 104 has a south pole that is facing the coil array 116 of the kinetic-energy harvester 101. In yet another example, the first orientation 108 of a magnet of the plurality of magnets 104 has a north pole that is facing a first side 103 of the magnet array 102. In other words, the axis defined by the north and south pole of the magnet is perpendicular to the length (L) of the cantilever beam spring 120. The second orientation 110 of a magnet of the plurality of magnets 104 has a north pole that is facing a second side 105 of the magnet array 102. Although the magnet array 102 in FIGS. 2 and 3 is shown with a first magnet at a corner of the magnet array 102 having the first orientation 108, in other examples, the first magnet at the corner of the magnet array 102 may have the second orientation 110, such that the next adjacent magnet has the first orientation 108.

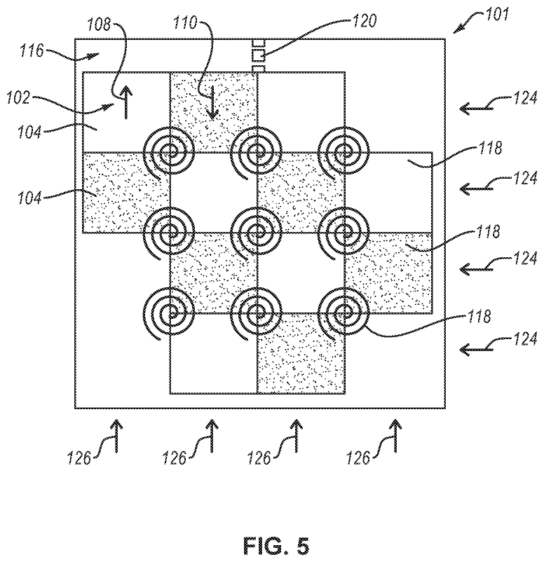

An interface 112 is between adjacent magnets of the plurality of magnets 104. In other words, adjacent magnets are positioned or arranged in a manner where one side of a magnet is in contact with one side of an adjacent magnet at the interface 112. The plurality of magnets 104 may be arranged in a single row. Alternatively, the plurality of magnets 104 of the magnet array 102 may be formed into a plurality of rows 124 and a plurality of columns 126. The pattern of alternating polarity continues throughout the magnet array 102, such that a magnet having the first orientation 108 is adjacent only to other magnets having the second orientation 110 in both rows 124 and columns 126 of the magnet array 102. Accordingly, diagonally adjacent magnets of the plurality of magnets 104 have the same orientation. The magnet array 102 may have a uniform number of magnets in each row 124 and column 126, such as a four-by-four grid. However, as shown in FIG. 5, it is not necessary to have a uniform number of magnets in each row 124 or column 126. Moreover, although in the illustrated example, the magnets 104 of the magnet array 102 are arranged into a four-by-four grid, so that the magnet array 102 includes sixteen magnets, in other examples, the magnet array 102 includes fewer or more than sixteen magnets. In one example, the magnet array 102 includes a single magnet. In another example, the magnet array 102 includes any quantity of magnets, without limitation, arranged in any of various arrangements, without limitation.

Each magnet 104 of the plurality of magnets 104 forms a portion of a coil-facing surface 106 of the magnet array 102. The coil-facing surface 106 of the magnet array 102 is the side or area of the magnet array 102 that directly faces the coil array 116 of the kinetic-energy harvester 100. In some examples, the coil-facing surface 106 of the magnet array 102 is a planar surface, such that the planar surface is co-planar with a vibration plane 122 of the coil array 116. Accordingly, the magnet array 102 and the coil array 116 are parallel to each other and an air-gap 130 is maintained between the surfaces. Moreover, a size and thickness (T) of each one of the plurality of magnets 104 may be the same, such that each one of the plurality of magnets 104 has uniform dimensions. Uniformity may help to maintain consistency and balance within the magnet array 102, promoting consistent magnetic field generation and efficient energy harvesting. In other examples, the coil-facing surface 106 of the magnet array 102 is non-planar, such as a coil-facing surface 106 that has a curved or irregular surface. For example, the coil-facing surface 106 of the magnet array 102 may have a convex or concave surface. Additionally, the coil array 116 may have a corresponding convex or concave surface, respectively. Such variations in the coil-facing surface 106 may allow for different modes of energy conversion and may be advantageous in specific applications or to accommodate mechanical or spatial constraints.

The coil array 116 is offset from the magnet array 102 in a first direction 132. That is, the air-gap 130 is defined between the coil-facing surface 106 of the magnet array 102 and the coil array 116. The air-gap 130 may be very small, to maintain the magnet array 102 and the coil array 116 in close proximity, while not allowing the magnet array 102 and the coil array 116 to come into direct contact. The coil array 116 includes a base 117 and at least one conductive coil 118. The conductive coil 118 is fixed to the base 117 of the coil array 116. The base 117 may be a printed circuit board. In one example, the coil array 116 is fabricated by etching the base 117 to selectively remove material from the base 117 and depositing the conductive coil 118 to the base 117 using an electroplating process to create the desired coil structure. In other examples, the conductive coil 118 to fixed to a surface of the base 117, such that the conductive coil 118 extends from the base 117.

The conductive coil 118 is made of a material having electric conductivity, such as a conductive coil 118 at least partially made of copper or a copper alloy. In some examples, the conductive coil 118 is formed of a copper wire that is wound around an air-cored ferrite ring. The conductive coil 118 is a planar coil that is coiled in a plane that is co-planar with or parallel to the vibration plane 122. The conductive coil 118 may have any of various geometries, including a circular or rectangular coil. In some examples, the conductive coil 118 may be a rectangular coil having a line length that is greater than a distance between each line spacing. For example, a rectangular coil may have a line length of 100 μm and a line spacing of 50 μm. Additionally, the conductive coil 118 can have any number of rings in the coil.

The conductive coil 118 of the coil array 116 is used to induce a current through the relative motion between the magnet array 102 and the coil array 116 of the kinetic-energy harvester 101. As the coil array 116 moves or vibrates in relation to the magnet array 102, the magnetic fields produced by the magnets change. These changing magnetic fields induce a voltage or electromotive force (EMF) across the conductive coil 118. This EMF then drives an electric current to flow through the conductive coil 118, completing the energy conversion process. The induced current in the conductive coil 118 represents the converted electrical energy, which can be harnessed for various purposes, such as powering other devices.

The coil array 116 also includes a transmitter (not shown). In some examples, the transmitter may be a transmitter coil having the same geometry and dimensions as the conductive coil 118. In other examples, the transmitter coil may have a different geometry and/or dimensions from the conductive coil 118. For example, the transmitter coil may have a coil diameter of about 280 μm. In other examples, the transmitter may be a transmitter antenna. The voltage generated by the conductive coil 118 is transferred to the transmitter, thereafter, the transmitter is configured to transmit the electrical power 214 to another device. In some cases, the transmitter is configured to transmit the electrical power 214 wirelessly using electromagnetic induction. In other cases, the transmitter is configured to transmit the electrical power 214 using a wired connection with another device.

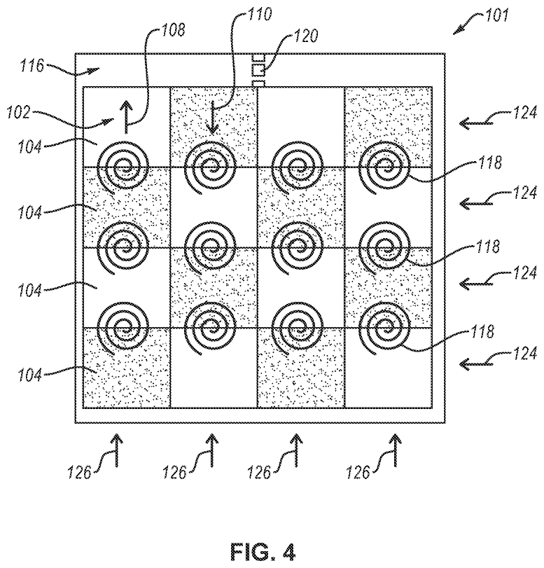

The conductive coil 118 of the coil array 116 is aligned in a second direction 134, parallel to the first direction 132, with the interface 112 between corresponding adjacent ones of the plurality of magnets 104. As shown in FIG. 4, the conductive coil 118 may be aligned with the interface 112 such that the conductive coil 118 is aligned with a side of each of two adjacent magnets of the plurality of magnets 104. Specifically, as shown, the magnet array 102 has a four-by-four grid of magnets having alternating polarity. A conductive coil 118 is aligned with each interface 112 between adjacent magnets along each column 126, such that each column has three conductive coils 118. In other examples, as shown in FIG. 5, the conductive coil 118 may be aligned with the interface 112 such that the conductive coil 118 is aligned with a quadripoint (i.e., meeting point) of at least three adjacent magnets. Specifically, as shown, the magnet array 102 has a non-uniform pattern of magnets in each row 124, such that some rows have different numbers of magnets. A conductive coil 118 is aligned with the interface 112 of at least three adjacent magnets, such that the conductive coil 118 is aligned with a corner of adjacent magnets. Accordingly, the coil array 116, in some examples, includes a plurality of conductive coils 118. Each one of the plurality of conductive coils 118 is aligned, in the second direction 134, with the interface 112 between corresponding adjacent ones of the plurality of magnets 104.

The kinetic-energy harvester 101 also includes the cantilever beam spring 120. The cantilever beam spring 120 couples together (e.g., extends between) the magnet array 102 and the coil array 116 to enable relative movement of the coil array 116 and the magnet array 102. The coil array 116 moves about a vibration plane 122 that is perpendicular to the first direction 132. That is, the coil array 116 moves relative to the vibration plane 122 in six degrees of freedom. Accordingly, the coil array 116 can move parallel to an x-axis of the vibration plane, parallel to a y-axis of the vibration plane, and perpendicular to a z-axis of the vibration plane, as well as rotation about each of the axes. When a vibration-generating object, to which the kinetic-energy harvester 101 is attached, generates vibrations, the cantilever beam spring 120 vibrates in accordance with the vibrations, which induces movement in the coil array 116 about the vibration plane 122. Accordingly, the cantilever beam spring 120 facilitates the interaction between the magnetic field generated by the magnet array 102 and the conductive coil 118 of the coil array 116.

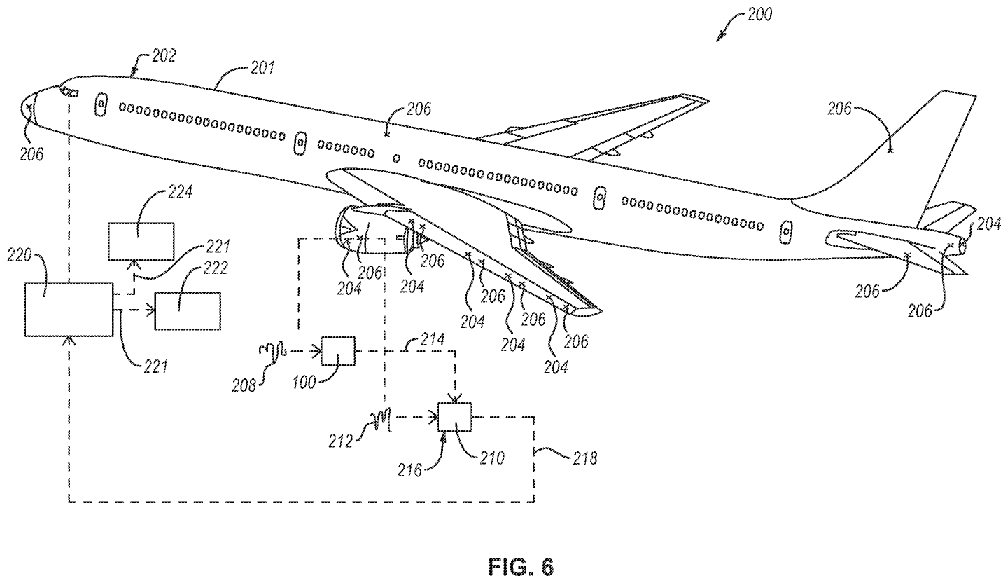

Referring to FIG. 6, one example of an acoustic detection system 200 is shown. The acoustic detection system 200 includes a vibration-generating object 201. The vibration-generating object 201 refers to any object capable of generating vibrations 208 that can be harnessed by a kinetic-energy harvester 100, such as the kinetic-energy harvester 101 described above, to convert mechanical vibrations into electrical power. That is, the vibration-generating object 201 serves as a source or originator of the vibrations 208 that the acoustic detection system 200 aims to utilize for energy conversion. It can be an object, or a component of an object, that is either designed to produce vibrations 208 intentionally or that naturally generates vibrations 208 as a byproduct of its operation. By capturing and utilizing these vibrations 208, the kinetic-energy harvester 100 efficiently transforms vibrations 208 into usable electrical power 214, enabling energy harvesting from the vibration-generation object 201. The electrical power 214 produced by the kinetic-energy harvester 100 is wirelessly transmitted to power further processes of the acoustic detection system 200.

In some examples, the vibration-generating object 201 is an aircraft 202. During flight, the aircraft 202 produces vibrations 208 at various locations on the aircraft, as a byproduct of the aircraft's operation, that can be harnessed by a kinetic-energy harvester 100. At least one kinetic-energy harvester 100 is embedded within a first location 204 of the aircraft 202. That is, the kinetic-energy harvester 100 is within an outer surface or skin of the aircraft 202, such that the kinetic-energy harvester 100 is not visible from the exterior of the aircraft 202. Consequently, in FIG. 6, the references to first locations 204 (and second locations 206, as described below) on the aircraft's exterior surface serve as representative indicators of the embedded locations. These references are used to illustrate the general areas where the kinetic-energy harvesters 100 are embedded within the aircraft's structure. By being embedded within the aircraft's outer surface, the kinetic-energy harvester 100 is protected from outside factors, while efficiently capturing and converting vibrations 208 into electrical power 214. The first location 204 can be any location on the aircraft 202 that generates vibrations 208. In some cases, first locations 204 are strategically chosen on the aircraft 202 due to a propensity of the first location 204 for generating reliable and robust vibrations 208. For example, first locations 204 can be embedded on the aircraft's wing, engine, and tail, as shown. However, it is important to note that a first location 204 can be situated at any location on the aircraft 202 that generates vibrations 208. The kinetic-energy harvester 100 is configured to convert the vibrations 208 generated at a corresponding first location 204, when the aircraft 202 is generating vibrations 208, such as when the aircraft 202 is in flight, to electrical power 214.

An acoustic sensor 210 is configured to receive electrical power 214 wirelessly from the kinetic-energy harvester 100 and is embedded within a second location 206, separate from the first location 204. Accordingly, the acoustic sensor 210 does not have an internal power supply, such as a battery, and relies on the kinetic-energy harvester 100 to supply electrical power 214. The second location 206 is a different location from the first location 204, where the kinetic-energy harvester 100 is located. In some examples, the second location 206 is very close to the first location 204, such that any energy loss from the transmission of the electrical power 214 is negligible. However, in other examples, the second location 206 may be a distance from the first location 204, such that some energy will be lost during the transmission of the electrical power 214 to the acoustic sensor 210. Accordingly, the kinetic-energy harvester 100 will need to transmit more electrical power 214 to the acoustic sensor 210 to overcome the energy loss. In some examples, the acoustic sensor 210 may have an energy storage unit (not shown), to store unused electrical power 214 received from the kinetic-energy harvester 100 to be stored until later use. In some examples, the acoustic sensor 210 has a receiver that is configured to receive the electrical power 214 from the kinetic-energy harvester 100. The receiver is positioned on the acoustic sensor 210 to effectively capture electromagnetic energy produced by the kinetic-energy harvester 100. By receiving the electrical power 214 through the receiver, the acoustic sensor 210 can harness the electrical power 214 for its operations. In other examples, the acoustic sensor 210 is configured to receive electrical power 214 through a wired connection with the kinetic-energy harvester 100.

The acoustic sensor 210 is configured to detect acoustic signals 212 approximate to the second location 206 on the aircraft 202. Acoustic signals 212 encompass a wide range of auditory or vibratory signatures, including but not limited to sounds, vibrations, or disturbances propagated through a medium such as air or solid material. In some examples, acoustic signals 212 indicate possible damage or performance issues with the aircraft 202. For example, acoustic signals 212 may indicate lightning, hail, and bird strikes to the aircraft 202. Additionally, acoustic signals 212 may indicate issues with the aircraft 202 such as cracks or corrosion on the aircraft or problems with misaligned, loose, or broken internal or external parts. Once the acoustic sensor 210 detects an acoustic signal 212, the acoustic sensor 210 performs a conversion process to transform the analog acoustic signal 212 into digital data, known as acoustic data 218. This acoustic data 218 typically includes various attributes of the detected acoustic signals 212, such as frequency, amplitude, duration, and any other relevant characteristics. Acoustic data 218 provides valuable insights and information about the captured sound or vibratory patterns and allows for further analysis, interpretation, and utilization in later applications. Generally, any noise, such as the natural vibrations approximate to the second location 206, will be removed by the acoustic sensor 210. By mitigating the effects of noise, the acoustic sensor 210 ensures that the resulting acoustic data 218 accurately represents the desired acoustic signals 212, indicating possible damage or performance issues.

In some examples, the acoustic sensor 210 is a MEMS-based acoustic sensor 216. The MEMS-based acoustic sensor 216 utilizes micro-electro-mechanical systems (MEMS) technology that integrates miniaturized mechanical and electrical components within the MEMS-based acoustic sensor 216. The compact size and precise microfabrication of the MEMS-based acoustic sensor 216 allows for high sensitivity and accurate detection of acoustic signals 212. The MEMS-based acoustic sensor 216 has the advantages of low power consumption, rapid response time, and compatibility with integrated circuitry for signal processing and wireless communication. Additionally, or alternatively, the acoustic sensor 210 may, in some examples, use resonant array acoustic sensing, involving the use of an array of resonant elements or sensors that vibrate at different, specific frequencies, such that the array collectively covers a range of frequencies. Accordingly, when an acoustic signal 212 matches the resonance frequency of one or more elements in the array, the element exhibits enhanced sensitivity, resulting in a more pronounced response.

The acoustic detection system 200 may have a plurality of kinetic-energy harvesters 100 and a plurality of acoustic sensors 210. In some examples, the plurality of kinetic-energy harvesters 100 and/or the plurality of acoustic sensors 210 are embedded uniformly about the aircraft 202 such that they are distributed or spaced out in a consistent manner. Uniform distribution allows for comprehensive coverage and reliable detecting and/or harvesting capabilities throughout the aircraft 202. In other examples, the plurality of kinetic-energy harvesters 100 and/or the plurality of acoustic sensors 210 are embedded non-uniformly about the aircraft 202. Non-uniform distribution enables focusing on specific areas or regions of the aircraft 202 where vibration generation or acoustic signal sources are expected to be more prominent. That is, a targeted approach allows for optimized detection or harvesting in critical or high-priority areas, or in a more efficient manner.

In some examples, each one of the plurality of kinetic-energy harvesters 100 corresponds to exactly one of the plurality of acoustic sensors 210. Accordingly, the electrical power 214 generated by one of the plurality of kinetic-energy harvesters 100 is wirelessly transmitted to a corresponding one of the plurality of acoustic sensors 210, enabling a direct and dedicated connection. By establishing a distinct pairing between kinetic-energy harvesters 100 and acoustic sensors 210, the acoustic detection system 200 facilitates seamless and targeted power transfer. In other examples, at least one of the plurality of kinetic-energy harvesters 100 corresponds to at least two of the plurality of acoustic sensors. Accordingly, the electrical power 214 generated by one of the plurality of kinetic-energy harvesters 100 is wirelessly transmitted to more than one (i.e., multiple) acoustic sensors 210, thus enabling simultaneous power supply to multiple acoustic sensors 210. This arrangement optimizes resource utilization by allowing a single kinetic-energy harvester 100 to provide power to multiple sensors simultaneously, thereby enhancing the system's overall efficiency and coverage. In yet other examples, a combination of one-to-one pairing and one-to-multiple pairing is used.

The acoustic detection system 200 may also include a controller 220 on or within the aircraft 202. The controller 220 is configured to wirelessly receive the acoustic data 218 transmitted from at least one acoustic sensor 210. Once received, the controller 220 processes the acoustic data 218 to processed acoustic data 221. The processed acoustic data 221 may be used to determine a current status at the second location 206, corresponding to the specific acoustic sensor 210, of the aircraft 202. That is, by analyzing the acoustic data 218, the controller 220 may determine the source of the acoustic data 218, such as specific damage or performance issues of the aircraft 202. The controller 220 may use signal processing, pattern recognition, machine learning, or other data analysis methods to identify patterns, anomalies, or specific characteristics in the acoustic data 218 that reflect the current status of the aircraft 202 at the second location 206. In some cases, the controller 220 is capable of determining the source of the acoustic data 218. That is, the controller 220 can identify specific damage or performance issues associated with the aircraft 202. The determination of the current status at the second location 206 allows for monitoring and assessing the performance, condition, or identifying any potential issues associated with the aircraft 202, enabling prompt and informed decision-making. For instance, the determination of its current status empowers the aircraft crew or ground crew to respond to any detected abnormalities, concerns, or failures. Timely interventions and actions can improve the AOG time duration and help ensure the safety, reliability, and optimal functioning of the aircraft 202.

The controller 220 may, in some examples, display the processed acoustic data 221 to a user of the aircraft 202. For example, the processed acoustic data 221 may be displayed to a user, such as a pilot, in a flight deck of the aircraft 202. The pilot may utilize the processed acoustic data 221 to enhance situational awareness of the aircraft 202 and to determine the need for any necessary adjustments or responses. The displayed processed acoustic data 221 serves as a visual representation, enabling the pilot to have real-time access to data related to the current conditions of the aircraft 202.

The controller 220 may be further connected to another power source, such as a battery, so the controller 220 does not rely on the electrical power 214 generated by the kinetic-energy harvester 100 to power its operation. Accordingly, the controller 220 is capable of conducting high-power processing of the acoustic data 218 to processed acoustic data 221, which may be processed through computational algorithms and signal processing techniques. The controller 220, in some examples, is connected to a data storage unit 222, which is configured to store the processed acoustic data 221 on the aircraft 202. Additionally, or alternatively, the processed acoustic data 221 is, in some examples, transmitted to a second controller 224, that is remote from the aircraft 202. For example, the second controller 224 may be a ground controller that ground crews monitoring the aircraft 202 can access. As such, ground crews can receive the processed acoustic data 221, prior to a visual inspection of the aircraft 202 by the ground crew, and even before the aircraft 202 lands at an airport. By obtaining the processed acoustic data 221 in advance, ground crews can prepare for any inspections, required repairs or maintenance, or preventative maintenance, prior to the landing of the aircraft 202.

The controller 220 and/or the second controller 224 may further process the processed acoustic data 221 to predict potential failures and timing of potential failures. By using the processed acoustic data 221 from multiple acoustic sensors 210, a phased array using the multiple acoustic sensors 210 acting together can provide referencing that can be used to make predictions or potential failures and timing. That is, the multiple acoustic sensors 210 can use predictive intelligence to predict future events. Additionally, the multiple acoustic sensors 210 can use prescriptive intelligence, such as artificial intelligence, for decision-making including proactive actions. In some examples, the multiple acoustic sensors 210 may include at least 100 individual acoustic sensors 210. In other examples, the multiple acoustic sensors 210 may include at least 1000 individual acoustic sensors 210. In yet other examples, the multiple acoustic sensors 210 includes between 100 and 1000 individual acoustic sensors 210. The multiple acoustic sensors 210 may be configured to detect acoustic signals at specific locations of the aircraft 202. For example, a phased array may be formed from multiple acoustic sensors 210 embedded within a flight control surface of the aircraft 202, such that characteristics of the flight control surface, like a stress and strain measurement, can be detected and measured.

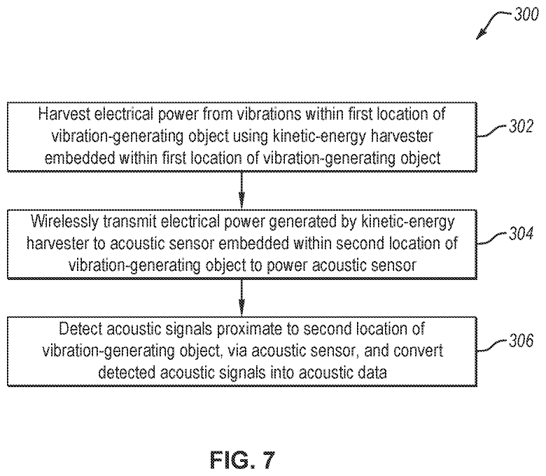

Referring to FIG. 7, according to some examples, a method 300 of detecting acoustic signals 212 from a vibration-generating object 201 is shown. The method 300 includes (block 302) harvesting electrical power 214 from vibrations within a first location of the vibration-generating object 201. The kinetic-energy harvester 100 is configured to convert vibrations 208 from the vibration-generating object 201 into electrical power 214. In some examples, the kinetic-energy harvester 100 may be configured to harvest electrical power 214 by inducing a current in at least one conductive coil 118 through the relative motion between a magnet array 102 and a coil array 116, such as the kinetic-energy harvester 100.

The method 300 also includes (block 304) wirelessly transmitting the electrical power 214 generated by the kinetic-energy harvester 100 to an acoustic sensor 210 embedded within a second location 206 of the vibration-generating object 201 to power the acoustic sensor 210. The second location 206 is separate from the first location 204. That is, the necessary power to operate the acoustic sensor 210 is wirelessly transmitted, rather than relying on the use of batteries or a direct physical connection to power the acoustic sensor 210. In some examples, the kinetic-energy harvester 100 is used to power more than one acoustic sensor 210. The acoustic sensor 210, in some examples, is a MEMS-based acoustic sensor 216, that uses MEMS technology to create a compact and precise microfabricated acoustic sensor.

The method 300 further includes (block 306) detecting acoustic signals 212 proximate to the second location 206 of the vibration-generating object 201 via the acoustic sensor 210, and processing the detected acoustic signals 212 into acoustic data 218. Acoustic signals 212 may encompass a wide range of auditory or vibratory signatures that are detected proximate to the second location 206. These acoustic signals 212 are processed to remove noise, such as the natural vibrations of the vibration-generating object 201. The vibrations generated by the vibration-generating object 201 can be separately measured and removed from the acoustic signals 212. The acoustic signals 212 may indicate possible damage or performance issues with the vibration-generating object 201. For example, detected acoustic signals 212 of an aircraft 202 may indicate lightning, hail, or bird strikes, or issues with the aircraft itself. The acoustic signals 212 may be generated on an exterior surface of the vibration-generating object 201 or within a surface of the vibration-generating object 201. The acoustic sensor 210 performs a conversion process to transform the analog acoustic signal 212 into digital data or acoustic data 218. Acoustic data 218 includes at least one characteristic of the acoustic sensor 210 such as frequency, amplitude, duration, voltage, magnitude, or other relevant characteristics.

In some examples, the acoustic sensor 210 has a memory unit that can store the acoustic data 218. In other examples, the method 300 further includes the acoustic sensor 210 wirelessly transmitting the acoustic data 218 to a controller 220 on the vibration-generating object 201. The controller is configured to process the acoustic data 218 to determine a current status of the vibration-generating object 201 at the second location 206.

The method 300 may, in some examples, also include transmitting the processed acoustic data 221 from the controller 220 to a second controller 224. The second controller 224 is remote from the vibration-generating object 201 and configured to analyze the processed acoustic data 221.

In the above description, certain terms may be used such as “up,” “down,” “upper,” “lower,” “horizontal,” “vertical,” “left,” “right,” “over,” “under” and the like. These terms are used, where applicable, to provide some clarity of description when dealing with relative relationships. But, these terms are not intended to imply absolute relationships, positions, and/or orientations. For example, with respect to an object, an “upper” surface can become a “lower” surface simply by turning the object over. Nevertheless, it is still the same object. Further, the terms “including,” “comprising,” “having,” and variations thereof mean “including but not limited to” unless expressly specified otherwise. An enumerated listing of items does not imply that any or all of the items are mutually exclusive and/or mutually inclusive, unless expressly specified otherwise. The terms “a,” “an,” and “the” also refer to “one or more” unless expressly specified otherwise. Further, the term “plurality” can be defined as “at least two.”

Additionally, instances in this specification where one element is “coupled” to another element can include direct and indirect coupling. Direct coupling can be defined as one element coupled to and in some contact with another element. Indirect coupling can be defined as coupling between two elements not in direct contact with each other, but having one or more additional elements between the coupled elements. Further, as used herein, securing one element to another element can include direct securing and indirect securing. Additionally, as used herein, “adjacent” does not necessarily denote contact. For example, one element can be adjacent another element without being in contact with that element.

As used herein, the phrase “at least one of”, when used with a list of items, means different combinations of one or more of the listed items may be used and only one of the items in the list may be needed. The item may be a particular object, thing, or category. In other words, “at least one of” means any combination of items or number of items may be used from the list, but not all of the items in the list may be required. For example, “at least one of item A, item B, and item C” may mean item A; item A and item B; item B; item A, item B, and item C; or item B and item C. In some cases, “at least one of item A, item B, and item C” may mean, for example, without limitation, two of item A, one of item B, and ten of item C; four of item B and seven of item C; or some other suitable combination.

Unless otherwise indicated, the terms “first,” “second,” etc. are used herein merely as labels, and are not intended to impose ordinal, positional, or hierarchical requirements on the items to which these terms refer. Moreover, reference to, e.g., a “second” item does not require or preclude the existence of, e.g., a “first” or lower-numbered item, and/or, e.g., a “third” or higher-numbered item.

As used herein, a system, apparatus, structure, article, element, component, or hardware “configured to” perform a specified function is indeed capable of performing the specified function without any alteration, rather than merely having potential to perform the specified function after further modification. In other words, the system, apparatus, structure, article, element, component, or hardware “configured to” perform a specified function is specifically selected, created, implemented, utilized, programmed, and/or designed for the purpose of performing the specified function. As used herein, “configured to” denotes existing characteristics of a system, apparatus, structure, article, element, component, or hardware which enable the system, apparatus, structure, article, element, component, or hardware to perform the specified function without further modification. For purposes of this disclosure, a system, apparatus, structure, article, element, component, or hardware described as being “configured to” perform a particular function may additionally or alternatively be described as being “adapted to” and/or as being “operative to” perform that function.

The schematic flow chart diagrams included herein are generally set forth as logical flow chart diagrams. As such, the depicted order and labeled steps are indicative of one example of the presented method. Other steps and methods may be conceived that are equivalent in function, logic, or effect to one or more steps, or portions thereof, of the illustrated method. Additionally, the format and symbols employed are provided to explain the logical steps of the method and are understood not to limit the scope of the method. Although various arrow types and line types may be employed in the flow chart diagrams, they are understood not to limit the scope of the corresponding method. Indeed, some arrows or other connectors may be used to indicate only the logical flow of the method. For instance, an arrow may indicate a waiting or monitoring period of unspecified duration between enumerated steps of the depicted method. Additionally, the order in which a particular method occurs may or may not strictly adhere to the order of the corresponding steps shown.

The present subject matter may be embodied in other specific forms without departing from its spirit or essential characteristics. The described examples are to be considered in all respects only as illustrative and not restrictive. All changes which come within the meaning and range of equivalency of the examples herein are to be embraced within their scope.

What is claimed is:

1. An acoustic detection system comprising:
a vibration-generating object;
a kinetic-energy harvester embedded within a first location of the vibration-generating object, configured to convert vibrations, at the first location of the vibration-generating object when the vibration-generating object is generating vibrations, into electrical power, and configured to wirelessly transmit the electrical power; and
an acoustic sensor embedded within a second location of the vibration-generating object, which is separate from the first location, wherein the acoustic sensor is configured to:
wirelessly receive the electrical power from the kinetic-energy harvester;
detect acoustic signals proximate to the second location of the vibration-generating object using the electrical power; and
convert detected acoustic signals into acoustic data.

2. The acoustic detection system of claim 1, further comprising a controller on the vibration-generating object configured to receive the acoustic data transmitted from the acoustic sensor and process the acoustic data to determine a current status at the second location of the vibration-generating object.

3. The acoustic detection system of claim 1, wherein the kinetic-energy harvester comprises:
a magnet array comprising a plurality of magnets arranged with alternating polarity and an interface between adjacent ones of the plurality of magnets, each magnet of the plurality of magnets forming a portion of a coil-facing surface of the magnet array;
a coil array comprising at least one conductive coil, wherein the coil array is offset from the magnet array in a first direction, such that an air-gap is defined between the coil-facing surface of the magnet array and the coil array, and wherein in a second direction parallel to the first direction the at least one conductive coil is aligned with the interface between corresponding adjacent ones of the plurality of magnets; and
a cantilever beam spring coupling with the magnet array to the coil array and configured to enable movement of the coil array, relative to the magnet array, about a vibration plane that is perpendicular to the first direction.

4. The acoustic detection system of claim 3, wherein the magnet array of the kinetic-energy harvester is fixed, relative to the vibration-generating object, such that the magnet array does not move relative to the vibration-generating object.

5. The acoustic detection system of claim 1, wherein the acoustic sensor comprises a MEMS-based acoustic sensor.

6. The acoustic detection system of claim 1, further comprising:
a plurality of kinetic-energy harvesters; and
a plurality of acoustic sensors;
wherein each one of the plurality of kinetic-energy harvesters corresponds to exactly one of the plurality of acoustic sensors, such that the electrical power generated by each one of the plurality of kinetic-energy harvesters is wirelessly transmitted to a corresponding one of the plurality of acoustic sensors.

7. The acoustic detection system of claim 1, further comprising:
a plurality of kinetic-energy harvesters; and
a plurality of acoustic sensors;
wherein at least one of the plurality of kinetic-energy harvesters corresponds to at least two of the plurality of acoustic sensors, such that the electrical power generated by each one of the plurality of kinetic-energy harvesters is wirelessly transmitted to at least two of the plurality of acoustic sensors.

8. The acoustic detection system of claim 1, wherein:
the vibration-generating object is an aircraft; and
the acoustic sensor is configured to detect acoustic signals to the aircraft for at least one of a lightning strike, a bird strike, a hail strike, a crack, a misalignment, a loose part, or a broken part.

9. A method of detecting acoustic signals from a vibration-generating object, the method comprising:
harvesting electrical power from vibrations within a first location of a vibration-generating object using a kinetic-energy harvester embedded within the first location of the vibration-generating object, the kinetic-energy harvester configured to convert the vibrations into electrical power;
wirelessly transmitting the electrical power generated by the kinetic-energy harvester to an acoustic sensor embedded within a second location of the vibration-generating object, separate from the first location, to power the acoustic sensor; and
detecting acoustic signals proximate to the second location of the vibration-generating object via the acoustic sensor, and processing the acoustic signals into acoustic data.

10. The method of claim 9, further comprising wirelessly transmitting the acoustic data from the acoustic sensor to a controller on the vibration-generating object, the controller configured to process the acoustic data to processed acoustic data determine a current status of the vibration-generating object at the second location.

11. The method of claim 10, further comprising transmitting the processed acoustic data from the controller to a second controller, remote from the vibration-generating object, the second controller configured to analyze the processed acoustic data.

12. The method of claim 10, wherein:
the step of harvesting electrical power from vibrations within a first location of a vibration-generating object using a kinetic-energy harvester further comprises harvesting electrical power from vibrations within a plurality of first locations of the vibration-generating object using a plurality of kinetic-energy harvesters each one embedded within a corresponding one of the plurality of first locations;
the step of wirelessly transmitting the electrical power generated by the kinetic-energy harvester to an acoustic sensor embedded within a second location further comprises wirelessly transmitting the electrical power generated by each one of the plurality of kinetic-energy harvesters to at least one of a plurality of acoustic sensors embedded within a corresponding one of a plurality of second locations; and
forming a phased array using the processed acoustic data from each one of the plurality of acoustic sensors to provide referencing for making predictive and prescriptive decisions about the vibration-generation object.

13. A kinetic-energy harvester, comprising:
a magnet array comprising a plurality of magnets arranged with alternating polarity and an interface between adjacent ones of the plurality of magnets, each magnet of the plurality of magnets forming a portion of a coil-facing surface of the magnet array;
a coil array comprising at least one conductive coil, wherein the coil array is offset from the magnet array in a first direction, such that an air-gap is defined between the coil-facing surface of the magnet array and the coil array, and wherein in a second direction parallel to the first direction the at least one conductive coil is aligned with the interface between corresponding adjacent ones of the plurality of magnets; and
a cantilever beam spring coupling the magnet array to the coil array and configured to enable movement of the coil array, relative to the magnet array, about a vibration plane that is perpendicular to the first direction.

14. The kinetic-energy harvester of claim 13, wherein a size and thickness of each one of the plurality of magnets is the same.

15. The kinetic-energy harvester of claim 13, wherein:
the plurality of magnets comprises two magnets adjacent each other;
a first one of the two magnets has a first orientation;
a second one of the two magnets has a second orientation; and
the first orientation is opposite the second orientation.

16. The kinetic-energy harvester of claim 13, wherein:
the coil array comprises a plurality of conductive coils, the at least one conductive coil being one of the plurality of conductive coils; and
each one of the plurality of conductive coils is aligned, in the second direction, with the interface between corresponding adjacent ones of the plurality of magnets.

17. The kinetic-energy harvester of claim 13, wherein:
the magnet array has a plurality of rows and a plurality of columns;
each magnet of the plurality of magnets has one of a first orientation or a second orientation that is opposite the first orientation; and
diagonally adjacent magnets of the plurality of magnets have a same orientation.

18. The kinetic-energy harvester of claim 13, wherein the at least one conductive coil is a planar coil that is coiled in a plane co-planar with or parallel to the vibration plane.

19. The kinetic-energy harvester of claim 13, wherein
the coil array further comprises a transmitter;
the at least one conductive coil is configured to forward electrical power produced by the at least one conductive coil to the transmitter; and
the transmitter is configured to transfer the electrical power wirelessly to a second device using electromagnetic induction.

20. The kinetic-energy harvester of claim 13, wherein:
the coil array further comprises a base; and
the at least one conductive coil is fixed to the base.
